(19) United States
(12) Patent Application Publication
(10) Pub. No.: US 2011/0241709 A1
(43) Pub. Date: Oct. 6, 2011

(54) Apparatus and method for measuring activity of plating solution

(75) Inventors: Young Ku Lyu, Anyang-si (KR); Tae Ho Kim, Suwon-si (KR); Jung Wook Seo, Hwaseong-si (KR); Hyo Seung Nam, Hwaseong-si (KR)

(73) Assignee: SAMSUNG ELECTRO-MECHANICS CO., LTD., Suwon (KR)

(21) Appl. No.: 12/805,215

(22) Filed: Jul. 19, 2010

(30) Foreign Application Priority Data
Apr. 1, 2010 (KR) 10-2010-0029798

(51) Int. Cl. G01N 27/06; G01R 27/08

(52) U.S. Cl. 324/693

(57) ABSTRACT

Disclosed herein are an apparatus and a method for measuring activity of a plating solution. The apparatus for measuring activity of a plating solution may include: a plating bath containing the plating solution for plating a plating object; a first electrode which is impregnated in the plating solution and has a plated body to measure current that flows in the plating solution and on the surface of the body in accordance with applied signal voltage; a second electrode which is impregnated in the plating solution to induce current from the first electrode or discharge current to the first electrode; a third electrode which controls the signal voltage applied to the first electrode to be constantly maintained; an impedance measurement unit which calculates an impedance value from the current measured in the first electrode; and a processing unit which displays a change of the calculated impedance value depending on a time.

### CROSS REFERENCE TO RELATED APPLICATION

This application claims the benefit of Korean Patent Application No. 10-2010-0029798, filed on Apr. 1, 2010, entitled “Apparatus And Method For Measuring Activity Of Plating Solution”, which is hereby incorporated by reference in its entirety into this application.

### BACKGROUND OF THE INVENTION

1. Technical Field

The present invention relates to an apparatus for measuring activity of a plating solution, and more particularly, to an apparatus and a method for measuring activity of a plating solution by measuring a change of an impedance value depending on a time.

2. Description of the Related Art

When a plating solution is first prepared or the plating solution is in a standby state in a plating bath for a long time, a plating degree of a product is decreased, causing a failure of the product.

In order to solve the problem, a dummy work in which a predetermined amount of dummy plating solution flows to the plating bath is in progress in order to maintain a proper plating state. At this time, activity of the plating solution is measured in order to determine the proper number of times of dummy work or determine the plating degree of the product in real time.

The known method for measuring the activity of the plating solution may adopt a weight measurement method indirectly estimating a plating thickness by measuring a weight before and after plating or a plating thickness measurement method using a measurement instrument. However, these methods have disadvantages in that the activity of the plating solution cannot be measured in real time and a worker should collect a directly plated sample as well as a change for a measurement time cannot be observed.

Another method for measuring the activity may adopt an electrical method such as a cyclic voltammetry. However, in such a method, a change of a component is measured by compulsorily applying a potential to an electrode, the method is not directly related to the activity of the plating solution and an undesired change of the plating solution the potential may be generated depending on the potential.

### SUMMARY OF THE INVENTION

The present invention is proposed to solve problems that may be generated in an apparatus and a method for measuring activity of a plating solution. More specifically, an object of the present invention is to provide an apparatus and a method for measuring activity of a plating solution capable of measuring the activity in real time without directly changing the plating solution.

An object of the present invention is to provide an apparatus for measuring activity of a plating solution. The apparatus for measuring activity of a plating solution may include: a plating bath containing the plating solution for plating a plating object; a first electrode which is impregnated in the plating solution and has a plated body to measure current that flows in the plating solution and on the surface of the body in accordance with applied signal voltage; a second electrode which is impregnated in the plating solution to induce current from the first electrode or discharge current to the first electrode; a third electrode which controls the signal voltage applied to the first electrode to be constantly maintained; an impedance measurement unit which calculates an impedance value from the current measured in the first electrode; and a processing unit which displays a change of the calculated impedance value depending on a time.

Herein, the processing unit may include a converter that converts the measured impedance value into the activity.

Further, the activity of the plating solution may be determined as a balance time in which a changing ratio of the measurement impedance value is constant.

In addition, the activity of the plating solution may be determined as a changing ratio of the measured impedance value within a range between a plating start time of the first electrode and the balance time when the changing ratio of the measured impedance value is constant.

Besides, the first electrode has a rod shape or a flat shape.

Moreover, the apparatus may further include an insulator exposing a predetermined portion of the surface of the first electrode and insulating the first electrode.

Further, the apparatus may further include a vibration member for vibrating the first electrode.

In addition, the first electrode may be impregnated to be inclined to the bottom of the plating bath at a predetermined angle.

Besides, the first electrode may be made of the same material as the plating object.

Moreover, the first electrode may be made of a material different from the plating object.

Further, the processing unit may further include a corrector correcting a change of the impedance value caused due to a difference in a material between the first electrode and the plating object.

Another object of the present invention is to provide a method for measuring activity of a plating solution. The method for measuring activity of a plating solution may include: measuring an impedance value in the plating solution and on the surface of a body of an electrode which is impregnated in the plating solution depending on a time; and converting the activity of the plating solution through a changing ratio of the measured impedance value.

Herein, the activity of the plating solution may be determined as a balance time in which a changing ratio of the measurement impedance value is constant.

In addition, the activity of the plating solution may be determined as a changing ratio of the measured impedance value within a range between a plating start time of the electrode and the balance time when the changing ratio of the measured impedance value is constant.

Besides, at the measuring the impedance value, vibration may be applied to the electrode.

Moreover, the electrode may be made of the same material as the plating object plated with the plating solution.

Further, the electrode may be made of a material different from the plating object plated with the plating solution.

In addition, the method may further include, after the measuring the impedance value, correcting the impedance value caused due to a difference in a material between the plating object and the electrode

### BRIEF DESCRIPTION OF THE DRAWINGS

FIG. 1 is a schematic diagram of an apparatus for measuring activity of a plating solution according to a first embodiment of the present invention;

FIGS. 2A to 2C are perspective views of a first electrode which can be adopted in an apparatus for measuring activity of a plating solution according to a first embodiment of the present invention; and

FIG. 3 is a schematic diagram of an apparatus for measuring activity of a plating solution according to a second embodiment of the present invention.

### DESCRIPTION OF THE PREFERRED EMBODIMENTS

Hereinafter, embodiments of the present invention will be described in detail with reference to the accompanying drawings of a method for measuring activity of a plating solution. In describing the present invention, well-known functions or constructions will not be described in detail since they may unnecessarily obscure the understanding of the present invention. In addition, terms described below as terms defined by considering their functions in the present invention may be changed depending on a user or operator's intention or a convention. Therefore, the definitions should be made on the basis of overall contents of the specification.

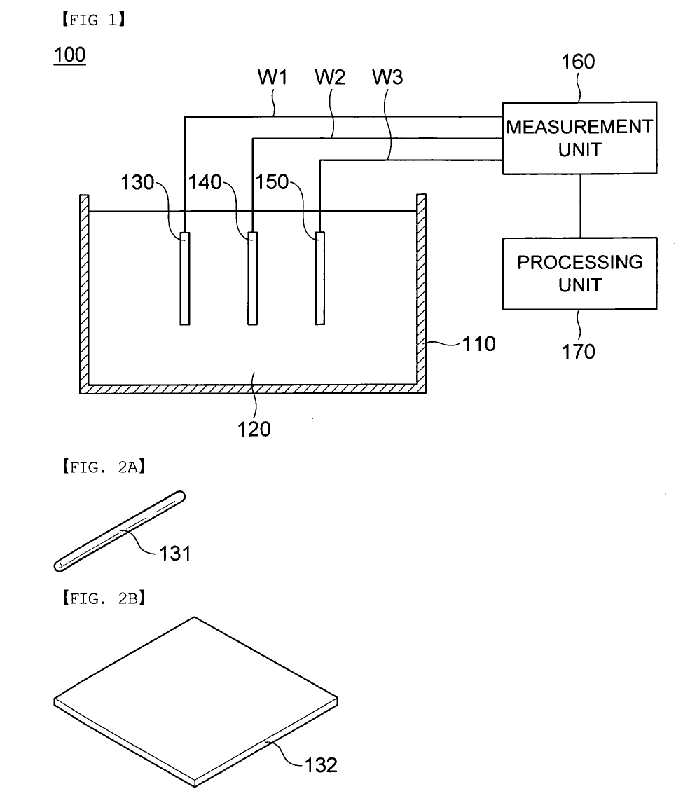

FIG. 1 is a schematic diagram of an apparatus for measuring activity of a plating solution according to a first embodiment of the present invention.

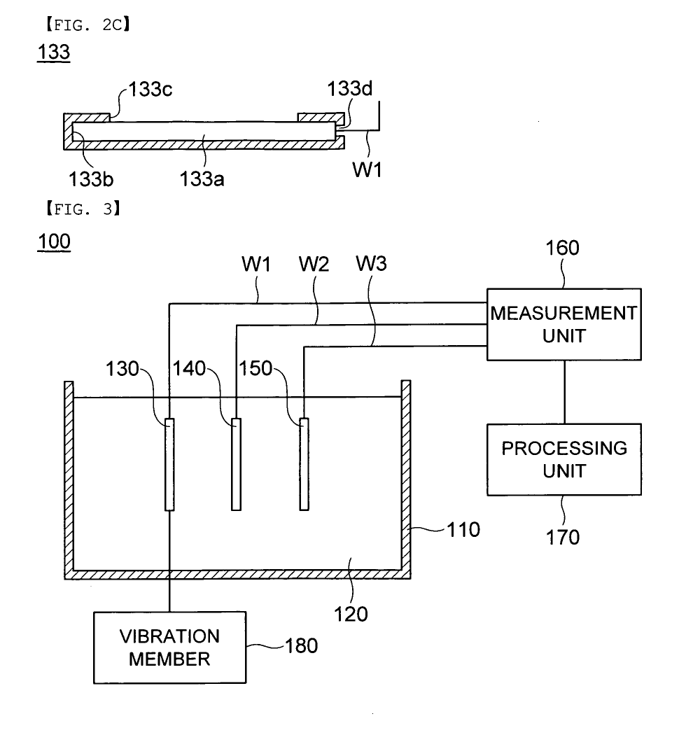

FIGS. 2A to 2C are perspective views of a first electrode which can be adopted in an apparatus for measuring activity of a plating solution according to a first embodiment of the present invention.

Referring to FIG. 1 and FIGS. 2A to 2C, the plating solution activity measuring apparatus 100 according to the first embodiment of the present invention may include a plating bath 110. The plating bath 110 contains a plating solution 120 containing metal ions to be plated. Herein, the plating solution 120 may be an electroless plating solution. Herein, a plating object may be plated by impregnating the plating object in the plating solution 120.

Further, the plating solution activity measuring apparatus 100 may include a first electrode 130, a second electrode 140, and a third electrode 150 that are impregnated in the plating solution of the plating bath 110 while being spaced from each other.

Herein, the first electrode 130 may measure current that flows on the plating solution 120 and a body of the first electrode 130 depending on signal voltage. At this time, the body of the first electrode 130 is plated.

The first electrode 130 may be inclined to the bottom of the plating bath 110 at a predetermined angle and may be impregnated in the plating solution 120. For example, the first electrode 130 may be impregnated vertically to the bottom of the plating bath 110. Therefore, it is possible to prevent hydrogen bubbles generated during plating from being absorbed onto the surface of the first electrode 130. Herein, the hydrogen bubbles influence the plating process performed in the first electrode 130 to thereby cause an error in measurement of the activity of the plating solution 120.

The first electrode 130 may have various shapes. For example, as shown in FIG. 2A, a first electrode 131 may have a rod shape. Alternatively, as shown in FIG. 2B, a first electrode 132 may have a flat panel shape. Herein, a flat first electrode 132 may be made of copper. Alternatively, the flat first electrode 132 may be formed of a substrate and copper plated on the surface of the substrate. However, in the embodiment of the present invention, the shape of the first electrode 130 is not limited.

Moreover, as shown in FIG. 2C, a first electrode 133 has a first opening 133c for exposing a predetermined portion of the surface of a body 133a and may further include an insulator 133b insulating the body. At this time, the surface of the body 133a of the first electrode 133 exposed by the first opening 133c may be plated. As a result, the first electrode 133 adjusts a dimension of the first opening 133c of the insulating 133b to have the same plating dimension as the plating object to be actually plated.

Moreover, the insulator 133b may further include a second opening 133d through which a part of the body 133a of the first electrode 133 is exposed to contact with a signal line W1.

Referring back to FIG. 1, the first electrode 130 may be made of the same material as the plating object. Moreover, the first electrode 130 may be made of the same material as the plating object and may have the same shape in order to more accurately measure the activity of the plating solution 120.

However, in the embodiment of the present invention, the material of the first electrode 130 is not limited thereto and the first electrode 130 may be made of materials different from the plating object, i.e., nickel, copper, gold, white gold, silver, graphite, glass, and ceramic.

The second electrode 140 is impregnated in the plating solution 120 to serve to induce current from the first electrode 130 or discharge current to the first electrode 130 depending on the applied potential.

The third electrode 150 may serve to constantly maintain signal voltage applied to the first electrode 130. That is, the third electrode 150 may serve to check and control whether or not the signal voltage is accurately applied to the first electrode 130.

Further, the plating solution activity measuring apparatus 100 may include an impedance measurement unit 160 that is electrically connected with the first electrode 130, the second electrode 140, and the third electrode 150 to apply the signal voltage and calculates an impedance value from the applied signal voltage and the current measured in the first electrode.

Herein, the first electrode 130, the second electrode 140, and the third electrode 150 and the impedance measurement unit 160 may be electrically connected with each other by signal lines W1, W2, and W3.

Further, the plating solution activity measuring apparatus 100 may include a processing unit 170 displaying the impedance value measured by the impedance measurement unit 160. Herein, the processing unit 170 may further include a converter converting the measured impedance value into the activity of the plating solution. At this time, the processing unit may display information on the activity of the plating solution to a worker. Further, the worker may easily operate the plating solution activity measuring apparatus 100 through the processing unit 170. At this time, the activity of the plating solution may be determined as a balance time in which a changing ratio of the measurement impedance value is constant. Alternatively, the activity of the plating solution may be determined as a changing ratio of an impedance value measured with respect to the balance time in which the changing ratio of the measured impedance value is constant.

Moreover, the processing unit 170 may further include a corrector correcting the change of the impedance value caused due to a difference in material between the first electrode 130 and the plating object.

Hereinafter, an apparatus for measuring activity of a plating solution according to a second embodiment of the present invention will be described with reference to FIG. 3. The second embodiment of the present invention has the same technological component as the first embodiment of the present invention except for a vibration member. Therefore, the same description as the first embodiment of the present invention will be omitted in the second embodiment of the present invention. Like reference numerals refer to like elements.

FIG. 3 is a schematic diagram of an apparatus for measuring activity of a plating solution according to a second embodiment of the present invention.

Referring to FIG. 3, the plating solution activity measuring apparatus 100 according to the second embodiment of the present invention may include a plating bath 110, a first electrode 130, a second electrode 140, a third electrode 150, an impedance measurement unit 160, and a processing unit 170.

Herein, the plating solution activity measuring apparatus 100 may determine the activity depending on the time of the plating solution 120 by measuring impedance values of the first electrode 130 and the plating solution 120 contained in the plating bath 110.

Moreover, the plating solution activity measuring apparatus 100 may further include a vibration member 180 for applying vibration to the first electrode 130. Herein, the vibration member 180 may serve to prevent hydrogen bubbles generated during plating from being absorbed onto the surface of the first electrode 130.

As a result, it is possible to prevent an error in measurement of the activity of the plating solution from being generated due to absorption of the hydrogen bubbles, thereby improving the accuracy in measurement of the activity of the plating solution.

Hereinafter, a method for measuring activity of a plating solution according to a third embodiment of the present invention will be described in detail. Herein, the plating solution activity measuring method will be described with reference to FIGS. 1 to 3.

In order to measure the activity of the plating solution 120, first, a first electrode 130, a second electrode 140, and a third electrode 150 are impregnated in the plating solution 120. Herein, the first electrode 130 may be made of the same material as a plating object. Moreover, the first electrode 130 may have the same shape as the plating object. Further, the same pretreatment process performed for the plating object is performed for the first electrode 130 and thereafter, the first electrode may be used to measure the activity of the plating solution. For example, when electroless copper plating is performed for the first electrode 130, the first electrode 130 includes plated copper on the surface of a substrate and palladium ions may be absorbed onto the copper surface as a catalyst. However, in the embodiment of the present invention, the plating material is not limited thereto and, for example, electroless gold plating and electroless nickel plating may be used.

From the time when the first electrode 130 is impregnated, plating the surface of a body of the first electrode 130 may be started. At this time, the concentration of the plating solution in the vicinity the first electrode 130 may be changed. For example, in the case of the electroless copper plating, copper ions of the plating solution in the vicinity of the first electrode 130 gradually decrease and hydrogen ions, etc., may be generated while plating. Further, a reducing agent of the solution in the vicinity of the first electrode 130 may also reduce copper ions.

The change in the concentration of the plating solution may cause impedance values of the surface of the first electrode 130 and the plating solution in the vicinity of the first electrode 130 to be changed. Herein, the change of the impedance value gradually decreases as a proceeding time of the plating process elapses. At this time, when the surface of the first electrode 130 starts to be constantly plated, the change of the impedance value may be balanced. As a result, the activity of the plating solution may be determined as a balance time. Alternatively, the activity of the plating solution may be determined as a changing ratio of an impedance value measured within the scope of the balance time in which the changing ratio of the measured impedance value is constant, that is, a change of the impedance value per hour.

Herein, in order to measure the activity of the plating solution, first, current that flows on the surface of the first electrode 130 depending on the applied signal voltage is measured. Thereafter, an impedance measurement unit 160 may calculate the impedance value on the basis of the measured current and the applied signal voltage.

A processing unit 170 may display an impedance value measured as time elapses, thus, a worker may monitor the change of the impedance value depending on the time. At this time, the processing unit 170 may convert the calculated impedance value into the activity and display it.

Herein, the activity of the plating solution may be determined as the balance time in which the changing ratio of the impedance value is constant. Alternatively, the activity of the plating solution may be determined as a changing ratio of the impedance value within a predetermined time range, i.e., from a plating start time to the balance time.

Thereafter, by comparing and correcting the activity of the plating solution in the processing unit 170 and a plating thickness value measured by an indirect weight measurement method or a direct analytical instrument, it is possible to prepare the plating thickness depending on the activity of the plating solution in a table form and store it.

Thereafter, by measuring the activity of the plating solution and using the stored table, a plating level, a plating thickness, and a plating time can be estimated to be thus used for controlling a plating process setting.

At this time, in the case in which the first electrode is different from the plating object, data on error rate of the impedance value depending on a difference in a material or a shape of the first electrode is built up through a pretest. Thereafter, the impedance value measured through the built-up data is corrected to be used for measuring the activity of the plating solution.

Further, vibration may be applied to the first electrode in order to prevent hydrogen bubbles from being absorbed onto the surface of the first electrode 130 while measuring the impedance value.

As a result, as described in the embodiments of the present invention, since the activity of the plating solution can be determined by measuring the changing ratio of the impedance value depending on the time, the activity of the plating solution does not directly influence compositions of the plating solution and the activity of the plating solution can be measured in real time.

Further, since an additional measurement substrate needs not be manufactured in order to measure the activity of the plating solution, and a degree of selection freedom for a material of the measurement substrate may be high.

In addition, it is possible to easily measure the activity without collecting an additional substrate and to shorten a measurement time.

According to an embodiment of the present invention, since a method for measuring activity of a plating solution can determine the activity of the plating solution by measuring a changing ratio of an impedance value depending on a time, the method can measure the activity of the plating solution in real time without directly influencing compositions of the plating solution.

Further, since an additional measurement substrate needs not be manufactured and the activity of the plating solution can be determined through correction in order to measure the activity of the plating solution, a degree of selection freedom for a material of the measurement substrate may be high.

In addition, it is possible to easily measure the activity without collecting an additional substrate and to shorten a measurement time

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. An apparatus for measuring activity of a plating solution, comprising:
a plating bath containing the plating solution for plating a plating object;
a first electrode which is impregnated in the plating solution and has a plated body to measure current that flows in the plating solution and on the surface of the body in accordance with applied signal voltage;
a second electrode which is impregnated in the plating solution to induce current from the first electrode or discharge current to the first electrode;
a third electrode which controls the signal voltage applied to the first electrode to be constantly maintained;
an impedance measurement unit which calculates an impedance value from the current measured in the first electrode; and
a processing unit which displays a change of the calculated impedance value depending on a time.

2. The apparatus for measuring activity of a plating solution according to claim 1, wherein the processing unit includes a converter that converts the measured impedance value into the activity.

3. The apparatus for measuring activity of a plating solution according to claim 2, wherein the activity of the plating solution is determined as a balance time when a changing ratio of the measured impedance value is constant.

4. The apparatus for measuring activity of a plating solution according to claim 2, wherein the activity of the plating solution is determined as a changing ratio of the measured impedance value within a range between a plating start time of the first electrode and the balance time when the changing ratio of the measured impedance value is constant.

5. The apparatus for measuring activity of a plating solution according to claim 1, wherein the first electrode has a rod shape or a flat shape.

6. The apparatus for measuring activity of a plating solution according to claim 1, further comprising an insulator exposing a predetermined portion of the surface of the first electrode and insulating the first electrode.

7. The apparatus for measuring activity of a plating solution according to claim 1, further comprising a vibration member for vibrating the first electrode.

8. The apparatus for measuring activity of a plating solution according to claim 1, wherein the first electrode is impregnated to be inclined to the bottom of the plating bath at a predetermined angle.

9. The apparatus for measuring activity of a plating solution according to claim 1, wherein the first electrode is made of the same material as the plating object.

10. The apparatus for measuring activity of a plating solution according to claim 1, wherein the first electrode is made of a material different from the plating object.

11. The apparatus for measuring activity of a plating solution according to claim 10, wherein the processing unit further includes a corrector correcting a change of the impedance value caused due to a difference in a material between the first electrode and the plating object.

12. A method for measuring activity of a plating solution, comprising:
measuring an impedance value in the plating solution and on the surface of a body of an electrode which is impregnated in the plating solution depending on a time; and
converting the activity of the plating solution through a changing ratio of the measured impedance value.

13. The method for measuring activity of a plating solution according to claim 12, wherein the activity of the plating solution is determined as a balance time when a changing ratio of the measured impedance value is constant.

14. The method for measuring activity of a plating solution according to claim 12, wherein the activity of the plating solution is determined as a changing ratio of the measured impedance value within a range between a plating start time of the electrode and the balance time when the changing ratio of the measured impedance value is constant.

15. The method for measuring activity of a plating solution according to claim 12, wherein at the measuring the impedance value, vibration is applied to the electrode.

16. The method for measuring activity of a plating solution according to claim 12, wherein the electrode is made of the same material as the plating object plated in the plating solution.

17. The method for measuring activity of a plating solution according to claim 12, wherein the electrode is made of a material different from the plating object plated in the plating solution.

18. The method for measuring activity of a plating solution according to claim 17, further comprising after the measuring the impedance value, correcting the impedance value caused due to a difference in a material between the plating object and the electrode.
